(19) United States
(12) Patent Application Publication
(10) Pub. No.: US 2025/0232098 A1
(43) Pub. Date: Jul. 17, 2025

(54) SIMULATING A MULTI-TUBING WELLBORE

(71) Applicant: Saudi Arabian Oil Company, Dhahran (SA)

(72) Inventors: Oshokhayamhe IIamah, Dhahran (SA); Rayan Alidi, Dhahran (SA)

(21) Appl. No.: 18/414,091

(22) Filed: Jan. 16, 2024

(51) Int. Cl. G06F 30/28; E21B 49/00

(52) U.S. Cl. CPC G06F 30/28; E21B 49/00; E21B 2200/20

(57) ABSTRACT

Techniques for modeling a reservoir include identifying a model of a wellbore that includes at least two tubing strings that are open in the wellbore and one or more fluid connections between the wellbore and a reservoir; assigning each of the at least two tubing strings as a single string pseudo-well in the model of the wellbore; numerically coupling the single string pseudo-wells together in the wellbore model; determining one or more well parameters for the modeled wellbore; and executing the modeled wellbore in a reservoir simulator to determine one or more wellbore fluid flow characteristics.

### TECHNICAL FIELD

The present disclosure describes systems and methods associated with simulating a multi-tubing wellbore and, more particularly, numerical modeling of wellbore fluid flow dynamics of multi-tubing wells in standard subsurface reservoir simulators.

### BACKGROUND

Standard reservoir simulators explicitly model fluid flow in the reservoir by discretizing the reservoir into grid cells. However, in these simulators, fluid flow within wellbores is not explicitly modelled. Instead, lookup tables that encapsulate well performance for a range of operating conditions are used to incorporate the influence of the wells in the reservoir simulation. If a well consists of two or more independent fluid flow paths that interact within the wellbore, it is sometimes useful to be able to explicitly model within wellbore fluid dynamics in the reservoir simulator.

### SUMMARY

In an example implementation, a computer-implemented method of modeling a reservoir includes identifying, with a control system, a model of a wellbore that includes at least two tubing strings that are open in the wellbore and one or more fluid connections between the wellbore and a reservoir; assigning, with the control system, each of the at least two tubing strings as a single string pseudo-well in the model of the wellbore; numerically coupling, with the control system, the single string pseudo-wells together in the wellbore model; determining, with the control system, one or more well parameters for the modeled wellbore; and executing, with the control system, the modeled wellbore in a reservoir simulator to determine one or more wellbore fluid flow characteristics.

In an aspect combinable with the example implementation, each of the at least two tubing strings is assigned as an independent single string pseudo-well having an open end within the wellbore that is fluidly connected to the reservoir through at least one of the one or more fluid connections.

Another aspect combinable with any of the previous aspects further includes assigning, with the control system, one or more non-neighbor connections between grid cells of an embedded discretized model of the reservoir and grid cells of a discretized model of a portion of the wellbore that includes the open end of each single string pseudo-well.

In another aspect combinable with any of the previous aspects, each of the one or more non-neighbor connections includes a virtual connection between two non-adjacent grid cells in the discretized model of the reservoir.

In another aspect combinable with any of the previous aspects, determining one or more well parameters for the modeled wellbore includes determining, with the control system, an effective permeability for each grid cell in a discretized model of at least a portion of the wellbore; and determining, with the control system, a well connection transmissibility factor between each single string pseudo-well and the discretized model of the portion of the wellbore.

In another aspect combinable with any of the previous aspects, a first tubing string includes an injector and a second tubing string includes a producer, and executing the modeled wellbore in a reservoir simulator to determine one or more wellbore fluid flow characteristics includes executing, with the control system, the modeled wellbore in the reservoir simulator to determine a composition and flow rate of a first fluid produced from the producer based on a second fluid injected into the reservoir from the injector and a reservoir fluid.

In another aspect combinable with any of the previous aspects, executing the modeled wellbore in the reservoir simulator to determine the composition and flow rate of the first fluid produced from the producer based on the second fluid injected into the reservoir from the injector and the reservoir fluid includes determining, with the control system, the composition and flow rate of the first fluid based on a volume weighted average composition of the second fluid and the reservoir fluid.

In another example implementation, a computing system includes one or more memory modules configured to store a model of a wellbore that includes at least two tubing strings that are open in the wellbore and one or more fluid connections between the wellbore and a reservoir; and one or more hardware processors communicably coupled to the one or more memory modules and configured to execute instructions stored on the one or more memory modules to perform operations. The operations include assigning each of the at least two tubing strings as a single string pseudo-well in the model of the wellbore; numerically coupling the single string pseudo-wells together in the wellbore model; determining one or more well parameters for the modeled wellbore; and executing the modeled wellbore in a reservoir simulator to determine one or more wellbore fluid flow characteristics.

In an aspect combinable with the example implementation, each of the at least two tubing strings is assigned as an independent single string pseudo-well having an open end within the wellbore that is fluidly connected to the reservoir through at least one of the one or more fluid connections.

In another aspect combinable with any of the previous aspects, the operations further include assigning one or more non-neighbor connections between grid cells of a discretized model of the reservoir and grid cells of a discretized model of a portion of the wellbore that includes the open end of each single string pseudo-well.

In another aspect combinable with any of the previous aspects, each of the one or more non-neighbor connections includes a virtual connection between two non-adjacent grid cells in the discretized model of the reservoir.

In another aspect combinable with any of the previous aspects, the operation of determining one or more well parameters for the modeled wellbore includes determining an effective permeability for each grid cell in a discretized model of at least a portion of the wellbore; and determining a well connection transmissibility factor between each single string pseudo-well and the discretized model of the portion of the wellbore.

In another aspect combinable with any of the previous aspects, a first tubing string includes an injector and a second tubing string includes a producer, and the operation of executing the modeled wellbore in a reservoir simulator to determine one or more wellbore fluid flow characteristics includes executing the modeled wellbore in the reservoir simulator to determine a composition and flow rate of a first fluid produced from the producer based on a second fluid injected into the reservoir from the injector and a reservoir fluid.

In another aspect combinable with any of the previous aspects, the operation of executing the modeled wellbore in the reservoir simulator to determine the composition and flow rate of the first fluid produced from the producer based on the second fluid injected into the reservoir from the injector and the reservoir fluid includes determining the composition and flow rate of the first fluid based on a volume weighted average composition of the second fluid and the reservoir fluid.

In another example implementation, an apparatus includes a tangible, non-transitory computer readable memory that includes instructions for causing one or more processors to perform operations including identifying a model of a wellbore that includes at least two tubing strings that are open in the wellbore and one or more fluid connections between the wellbore and a reservoir; assigning each of the at least two tubing strings as a single string pseudo-well in the model of the wellbore; numerically coupling the single string pseudo-wells together in the wellbore model; determining one or more well parameters for the modeled wellbore; and executing the modeled wellbore in a reservoir simulator to determine one or more wellbore fluid flow characteristics.

In an aspect combinable with the example implementation, each of the at least two tubing strings is assigned as an independent single string pseudo-well having an open end within the wellbore that is fluidly connected to the reservoir through at least one of the one or more fluid connections.

In another aspect combinable with any of the previous aspects, the operations further include assigning one or more non-neighbor connections between grid cells of a discretized model of the reservoir and grid cells of a discretized model of a portion of the wellbore that includes the open end of each single string pseudo-well.

In another aspect combinable with any of the previous aspects, each of the one or more non-neighbor connections includes a virtual connection between two non-adjacent grid cells in the discretized model of the reservoir.

In another aspect combinable with any of the previous aspects, the operation of determining one or more well parameters for the modeled wellbore includes determining an effective permeability for each grid cell in a discretized model of at least a portion of the wellbore; and determining a well connection transmissibility factor between each single string pseudo-well and the discretized model of the portion of the wellbore.

In another aspect combinable with any of the previous aspects, a first tubing string includes an injector and a second tubing string includes a producer, and the operation of executing the modeled wellbore in a reservoir simulator to determine one or more wellbore fluid flow characteristics includes executing the modeled wellbore in the reservoir simulator to determine a composition and flow rate of a first fluid produced from the producer based on a second fluid injected into the reservoir from the injector and a reservoir fluid.

In another aspect combinable with any of the previous aspects, the operation of executing the modeled wellbore in the reservoir simulator to determine the composition and flow rate of the first fluid produced from the producer based on the second fluid injected into the reservoir from the injector and the reservoir fluid includes determining the composition and flow rate of the first fluid based on a volume weighted average composition of the second fluid and the reservoir fluid.

Implementations of systems and methods according to the present disclosure can include one, some, or all of the following features. For example, implementations according to the present disclosure can provide flexible and accurate numerical modelling of wellbore fluid flow dynamics for multi-tubing wells in standard reservoir simulators. For instance, implementations according to the present disclosure do not require specialized simulation software and can be implemented in standard off-the-shelf reservoir simulators in a non-intrusive fashion. As another example, implementations according to the present disclosure can support all conceivable types of multi-tubing wells. Further, unlike a “Secondary Well” feature in commercial simulators, which has severely limited well control options, implementations according to the present disclosure can offer flexibility and full well control options, including support for wells where the tubing strings have different and/or variable operating modes (for example, one tubing is injecting while the other tubing is producing).

The details of one or more implementations of the subject matter described in this disclosure are set forth in the accompanying drawings and the description below. Other features, aspects, and advantages of the subject matter will become apparent from the description, the drawings, and the claims.

### BRIEF DESCRIPTION OF THE DRAWINGS

FIGS. 1A and 1B are schematic illustrations of elements of a model of a multi-tubing well in a reservoir simulator according to the present disclosure.

FIG. 1C is a flowchart that illustrates an example reservoir modeling method according to the present disclosure.

FIG. 2 is a schematic illustration of an example implementation of a wellbore model with a single string pseudo wells that are numerically coupled together via a common contiguous group of grid cells to represent a discretized common segment of a wellbore of a multi-tubing well according to the present disclosure.

FIG. 3 is another schematic illustration of an example implementation of a wellbore model with non-neighbor connections between reservoir grid cells in a reservoir simulation grid that actually hosts the wellbore and discretized wellbore cells according to the present disclosure.

FIG. 4 is another schematic illustration of an example implementation of a reservoir cross-section showing horizontal multi-tubing well to be modeled according to the present disclosure.

FIG. 5 is a graph of an aerial view of an augmented simulation grid showing a discretized reservoir, discretized wellbore, and pseudo well connections that represent a shorter tubing and a longer tubing according to the present disclosure.

FIG. 6 is another graph of an aerial view of an augmented simulation grid showing a discretized reservoir, discretized wellbore, and pseudo well connections that represent multiple tubings according to the present disclosure.

FIG. 7 is a graph that represents a modeled multi-tubing well production stream of acid gas concentration according to the present disclosure.

FIG. 8 shows a schematic drawing of a control system that can be used to model a wellbore and simulate a reservoir with a modeled multi-tubing wellbore according to the present disclosure.

### DETAILED DESCRIPTION

The present disclosure describes implementations of computer-implemented systems, apparatus, and methods for joint numerical modelling of subsurface reservoir and wellbore fluid flow dynamics of multi-tubing wells. Example implementations of the present disclosure can simplify the complex problem of explicitly modeling multi-tubing wells in a reservoir simulator by representing a multi-tubing well with multiple, standalone, single tubing (string) pseudo wells, which are more efficiently modeled. To mimic a multi-tubing well, the standalone pseudo wells can be numerically coupled together via a common, discretized wellbore that is embedded in an augmented simulation grid. Example implementations can also allow the simulation of reservoir and wellbore dynamics of multi-tubing wells in conventional reservoir simulators; namely, simulators that are not specifically designed or programmed for multi-tubing wellbore simulation. Thus, example implementations according to the present disclosure can provide for reservoir simulation of wellbore fluid dynamics (for example, fluid mixing), steam assisted gravity drainage, and other areas where multi-tubing wells are required or desirable.

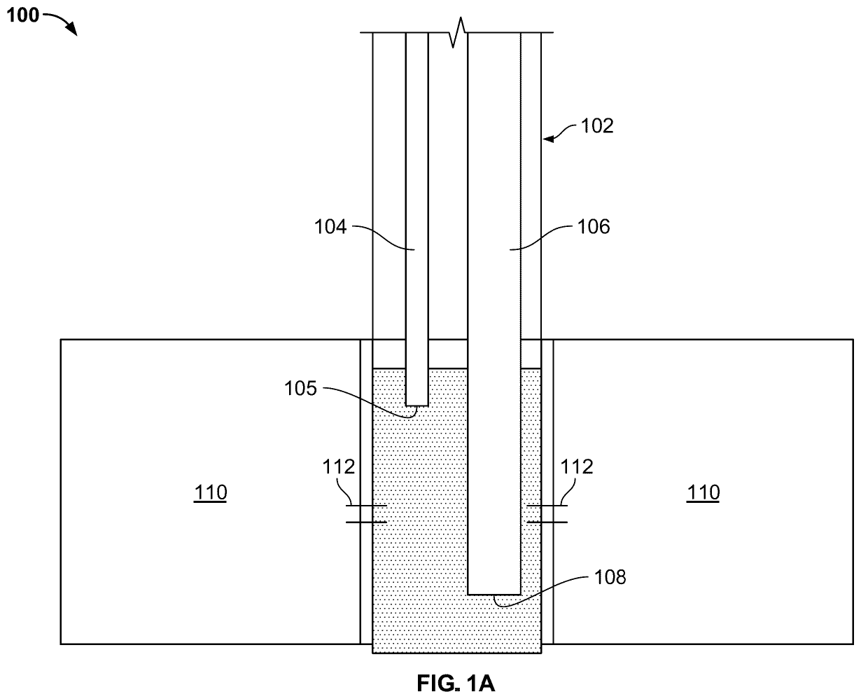

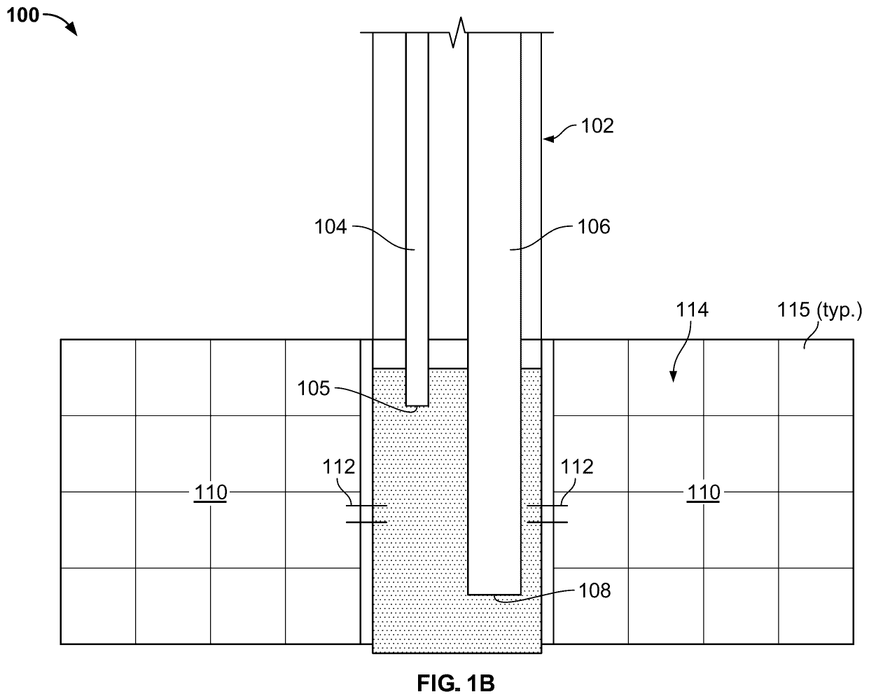

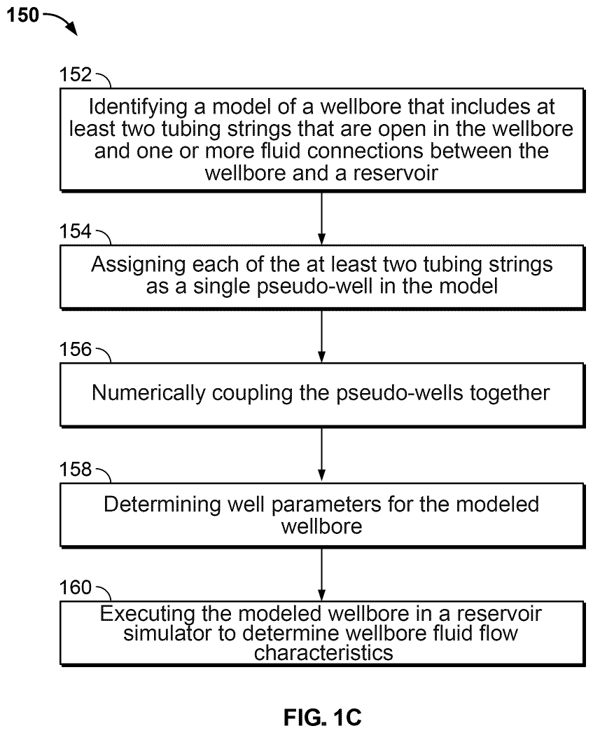

FIGS. 1A and 1B are schematic illustrations of elements of a model 100 of a multi-tubing well (wellbore model 100) in a reservoir simulator according to the present disclosure. Generally, wellbore model 100 (and models according to the present disclosure) include: two or more tubing strings through which fluid flows out of or into the wellbore, a wellbore into which the tubing strings open, and one or more connections between the wellbore and the reservoir (as divided in the model into grid cells). For example, wellbore model 100 represents a model of a wellbore 102 formed into a reservoir 110 (for example, from a terranean surface, whether under a body of water or otherwise). The wellbore 102 includes at least two tubings 104 and 106 (for example, production casings or strings, injection tubings or strings, or a combination thereof) that extend through the wellbore 102 and have respective open ends 105 and 108 that are in fluid communication with the reservoir 110 through one or more fluid connections 112 (for example, open hole, perforations, fractures, whether natural or hydraulic or both, or a combination thereof).

As shown in FIG. 1B, the reservoir 110 in which these features of the model 100 are modeled is discretized on a grid 114 that includes multiple grid cells 115. As explained herein, the multi-tubing wellbore is also discretized such that a reservoir simulator can determine certain fluid flow properties of the wellbore 102, as well as properties of the reservoir 110, on a grid cell-by-grid cell basis.

FIG. 1C is a flowchart that illustrates an example reservoir modeling method 150 according to the present disclosure. For example, using wellbore model 100, a modeling process executed by a conventional reservoir simulator (in other words, a simulator not specifically designed or programmed to simulate a multi-tubing wellbore) can determine wellbore fluid flow dynamics for multi-tubing wells.

Method 150 can begin at step 152, which includes identifying a model of a wellbore that includes at least two tubing strings that are open in the wellbore and one or more fluid connections between the wellbore and a reservoir. For example, wellbore model 100 comprises the wellbore 102 that includes at least tubing strings 104 and 106, each of which is fluidly connected to the reservoir 110 through fluid connections 112 and open ends 105 and 108, respectively.

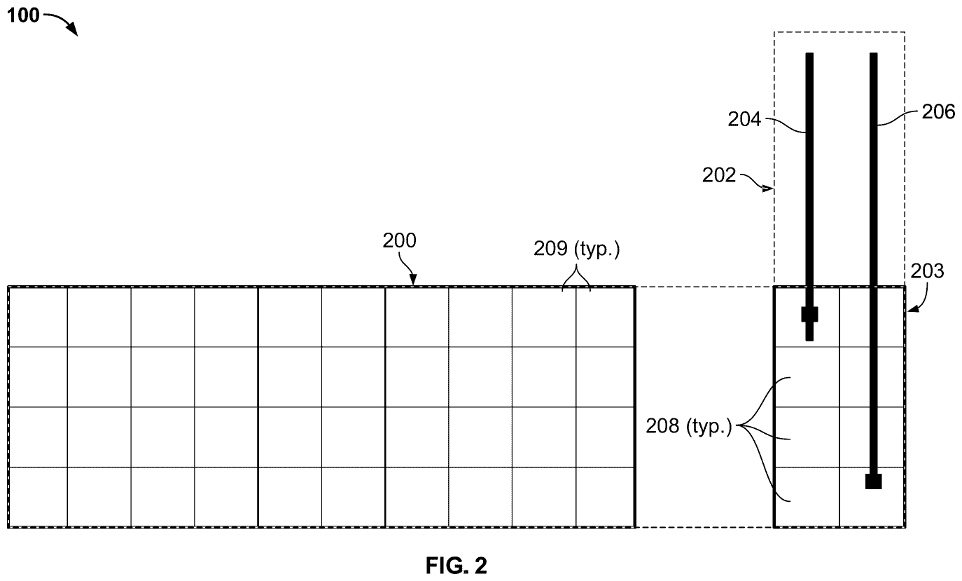

Method 150 can continue at step 154, which includes assigning each of the at least two tubing strings as a single string pseudo-well in the model. For example, turning to FIG. 2, this figure shows a schematic illustration of the wellbore model 100 with the tubings represented as single string pseudo wells 204 and 206 within an embedded discretized wellbore 202 formed in a discretized reservoir 200. Thus, in this example, the tubing strings 104 and 106 of the complex multi-tubing wellbore 102 are represented using a set of single string (in other words, a single tubing) pseudo wells 204 and 206 in the reservoir simulator. Each of the resulting single string pseudo wells 204 and 206 is declared in the reservoir simulator as if it were a standalone well, with its own independent well (production or injection) controls, flow performance tables, and result vectors. The representation of tubings 104 and 106 as pseudo wells 204 and 206 provides flexibility in how each tubing of a multi-tubing well is controlled and simulated.

Method 150 can continue at step 156, which includes numerically coupling the pseudo-wells together. In this example, pseudo wells 204 and 206 are numerically coupled together via a common contiguous group of grid cells to represent a discretized common segment of the embedded discretized wellbore 202. Through the numerical coupling of the pseudo wells 204 and 206 together via the common contiguous group of grid cells 208 representing the discretized common segment 203 of the embedded discretized wellbore 202 of the multi-tubing well (as shown in FIG. 2), the otherwise independent pseudo wells 204 and 206 can interact with each other in the reservoir simulator, mimicking the behavior of the multi-tubing wellbore 202. In some aspects, by discretizing the common segment 203 of the embedded discretized wellbore 202 wellbore fluid dynamics (for example, pressures, compositions, etc.) can be explicitly simulated by the reservoir simulator.

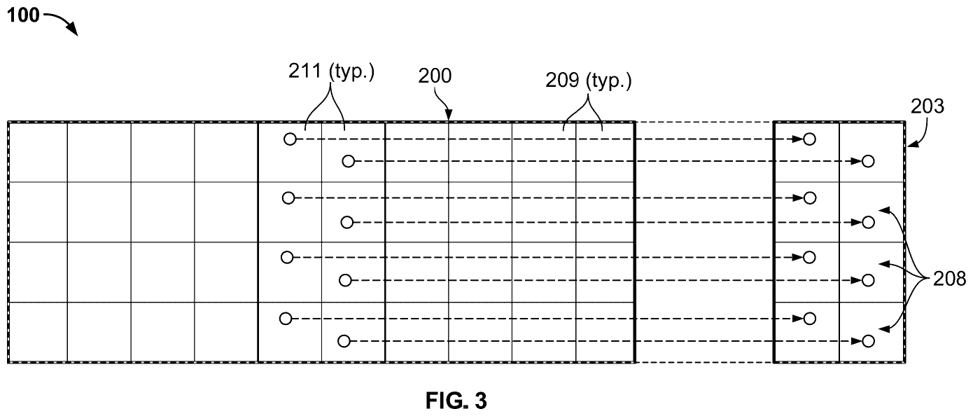

As part of step 156, grid cells 208 that represent the discretized wellbore 203 are an extension of the original reservoir simulation grid 114 (in the discretized reservoir 200). In the resulting augmented simulation grid, the embedded discretized wellbore grid cells 208 are physically separated from reservoir grid cells 209 in the original reservoir simulation grid 114 that actually hosts the embedded discretized wellbore 202. This issue can be addressed by the use of non-neighbor connections (NNCs) 211 as shown in FIG. 3. NNCs 211 can enable a virtual connection between any two grid cells (209 and 208) in the simulation grid, regardless of whether the cells are physically adjacent or separated with respect to each other. The NNCs 211 can ensure that the embedded discretized wellbore grid cells 208 connect to and directly interact with the reservoir grid cells 209 in the original reservoir simulation grid 114 that actually hosts the wellbore 102, as required, even though they are physically separated. Thus, use of standalone, discretized pseudo wells 204 and 206 can represent complex multi-tubing wells of any kind in a reservoir simulator.

Method 150 can continue at step 158, which includes determining well parameters for the modeled wellbore. For example, the grid cells 208 representing the embedded discretized wellbore 202 are specified such that their total pore volume corresponds to the volume of the common segment 203 of the wellbore 102 in the multi-tubing well. Each discretized wellbore grid cell 208 effective permeability can be determined from Hagen-Poiseuille equation for laminar flow in a pipe in step 156. Furthermore, in step 158, a well connection transmissibility factor between the pseudo wells 204 and 206 and the embedded discretized wellbore 202 can be calculated using the normal equations for well connection transmissibility factors, using the discretized wellbore grid cell effective permeabilities as input.

The NNC transmissibility factors between a discretized wellbore grid cell 208 and its corresponding host reservoir grid cells 209 can correspond to the well connection transmissibility factors between the original multi-tubing wellbore 102 and the reservoir grid cells 114. Hence, these NNC transmissibility factors can be determined using the normal equations for well connection transmissibility factors; however, in this case, the host reservoir grid cells 115 permeabilities are used as input.

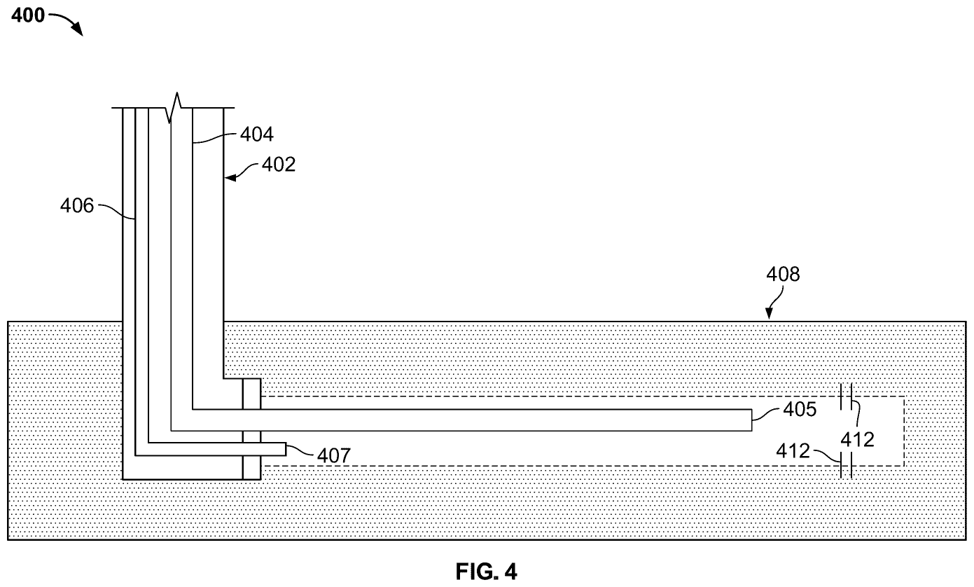

Method 150 can continue at step 160, which includes executing the modeled wellbore in a reservoir simulator to determine wellbore fluid flow characteristics. Example reservoir simulators include, for instance, Schlumberger ECLIPSE and CMG GEM (as commercial simulators) and Saudi Aramco GigaPOWERS (as a proprietary simulator), among others. For example, a reservoir simulator was used to perform a simulation to determine wellbore fluid flow characteristics according to the previous steps 152-158 to build a wellbore model of a wellbore similar to that shown in FIG. 4. FIG. 4 is an illustration of a wellbore model 400 that models a horizontal multi-tubing wellbore 402 that includes tubings 404 and 406. The tubings 404 and 406 in the model 400 include respective open ends 405 and 407 that are fluidly connected to a reservoir 408 through fluid connections 412 (for example, perforations or fractures or open hole).

In this example, the modeled wellbore 400 executed in the reservoir simulator includes a notional homogeneous reservoir 408 with one horizontal multi-tubing wellbore 402 as shown in FIG. 4. The reservoir 408 is initialized with a sour gas condensate fluid with an H₂S concentration of 20.4 mol % H₂S. The tubing 406 injects sweet gas with no H₂S (in other words, 0 mol % H₂S) into the wellbore 402. The tubing 404 produces gas from the wellbore 402, which is a mixture of a sour in-situ reservoir gas and the injected sweet gas. In accordance with steps 152-158, the reservoir 408 is simulated in step 160 with the multi-tubing wellbore 402 under a constant (steady-state) well operation injecting 5 MMSCFD of sweet gas (through tubing 406) and producing 10 MMSCFD of diluted or mixed gas (through tubing 404).

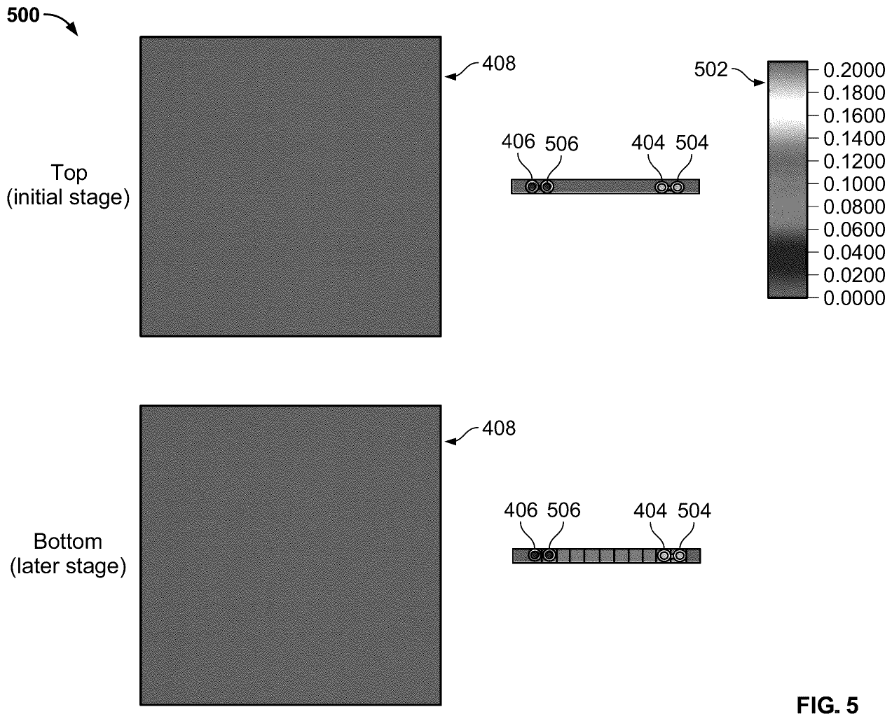

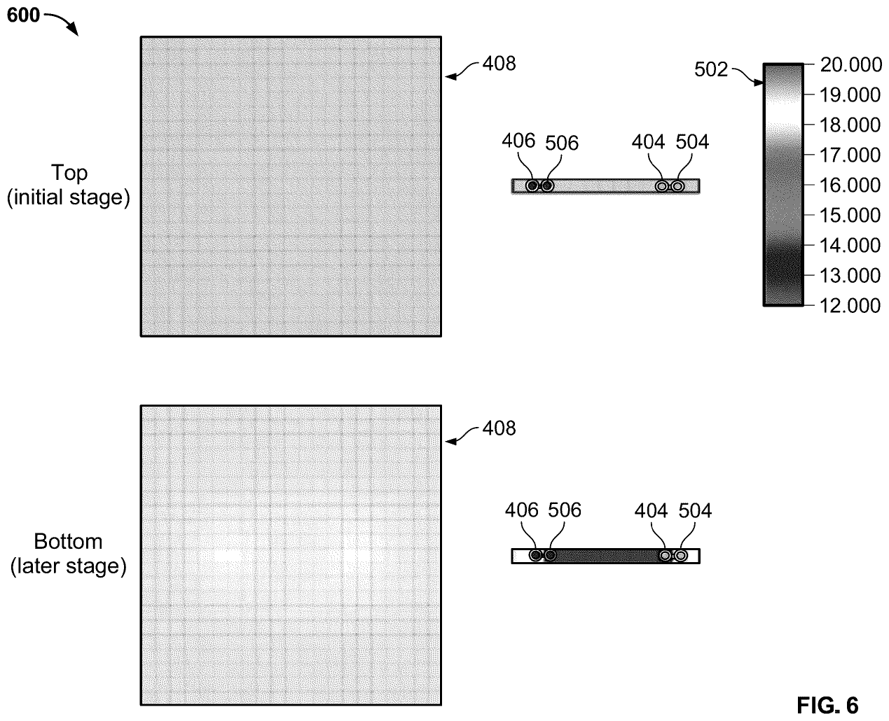

Once the multi-tubing well operation starts, the discretized wellbore (wellbore 402) provides for modeling of the wellbore fluid dynamics. For example, the variation in fluid H₂S concentration and densities within the wellbore can be explicitly modeled in the reservoir simulator in step 160, as shown in FIGS. 5 and 6. For this homogeneous, single well reservoir case with steady-state well operation, the resulting well production stream H₂S composition can be estimated analytically, as the volume weighted average composition of the injected sweet gas and the produced sour reservoir gas. This estimation can proceed according to:

$${z}_{d} \approx \frac{( {v}_{r} \times {z}_{r} ) + ( {v}_{i} + {z}_{i} )}{{v}_{r} + {v}_{i}} . \qquad Eq . 1$$

In Eq. 1, vᵣ is the produced reservoir in-situ gas stream volume, Zᵣ is the produced reservoir in-situ gas stream H₂S concentration, vᵢ is the injected sweet gas stream volume, zᵢ is the injected sweet gas stream H₂S concentration, and Z_{d} is the diluted or mixed produced gas stream H₂S concentration.

FIG. 5 is a graph 500 of aerial views (top and bottom, which represent different well operation stages) of an augmented simulation grid showing the discretized reservoir, discretized wellbore, and pseudo well connections that represent multiple tubing according to the present disclosure. The discretized reservoir 408 is shown in grid cells. The connections 406 and 506 of the first single string pseudo well and the connections 404 and 504 of the second single string pseudo well are also shown, along with a modeled fluid composition within the segment of the multi-tubing well wellbore between 405 and 407. The illustrated grid cell colors represent H₂S concentrations in mol fractions at an initial (top aerial view) and later (bottom aerial view) stage of well operation of the simulated wellbore 402.

FIG. 6 is a graph 600 of aerial views (top and bottom, which represent different well operation stages) of an augmented simulation grid showing the discretized reservoir, discretized wellbore, and pseudo well connections that represent multiple tubing according to the present disclosure. The discretized reservoir 408 is shown in grid cells. The connections 406 and 506 of the first single string pseudo well and the connections 404 and 504 of the second single string pseudo well are also shown, along with a modeled fluid composition within the segment of the multi-tubing well wellbore between 405 and 407. The illustrated grid cell colors represent gas density in lbm/ft³ at an initial (top aerial view) and later (bottom aerial view) stage of well operation of the simulated wellbore 402.

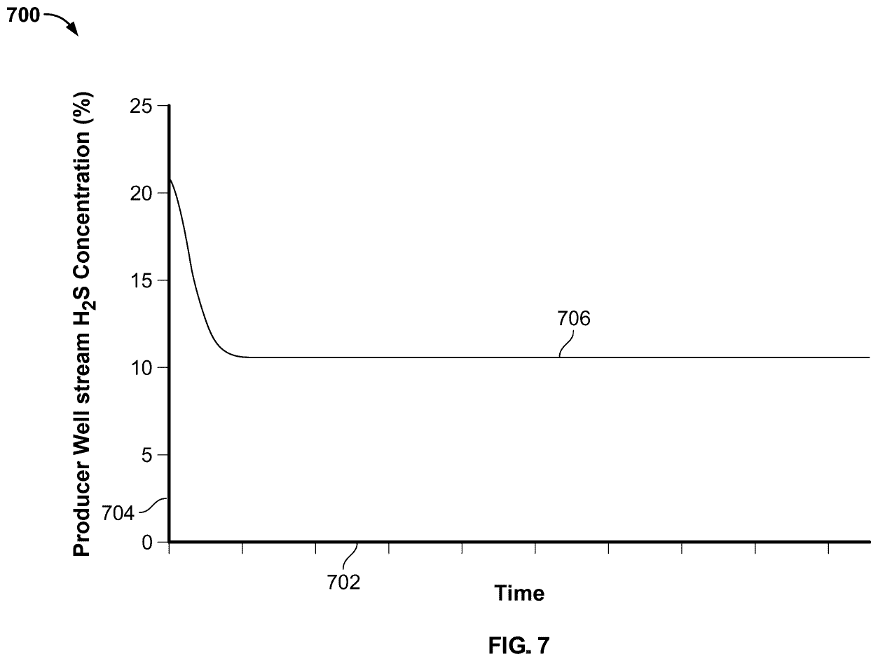

It should be noted that Eq. 1 assumes isothermal conditions and full mixing within the wellbore 402 (in other words, idealized conditions). Using Eq. 1, a diluted or mixed produced gas stream H₂S concentration of 10.2 mol % H₂S is estimated. Applying method 150 in the reservoir simulator, a diluted or mixed produced gas stream H₂S concentration of 10.37 mol % H₂S is obtained once the early time transient effects subside as shown in FIG. 7.

FIG. 7 is a graph 700 that represents the modeled multi-tubing well production stream of H₂S concentration. As shown in graph 700, the H₂S concentration curve 706 shows the concentration (measured on y-axis 704) over time (measured on x-axis 702) that eventually reaches about 10 mol % H₂S after the transient effects subside. The estimated and simulated produced gas stream H₂S concentration are comparable, confirming that the example method 150 is capable of modeling within wellbore fluid flow dynamics in multi-tubing wells.

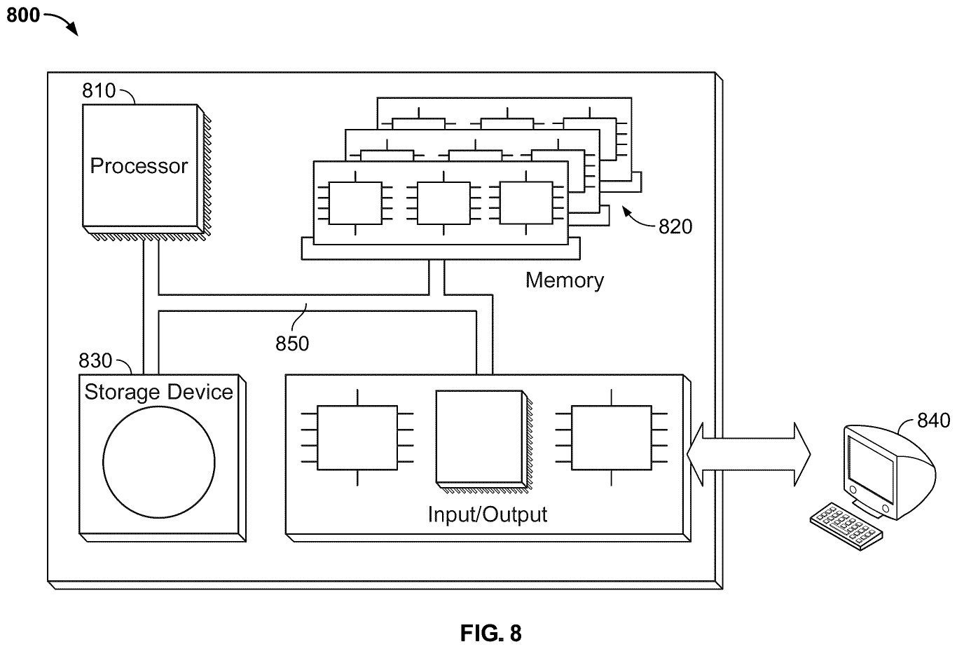

FIG. 8 shows a schematic drawing of a control system 800 that can be used to build and execute a wellbore model and a reservoir simulator according to the present disclosure. Some or all of the example control system 800 can be implemented as cloud-based system and/or service, alone or in combination with other portions of the example control system 800 that can be implemented to execute. The controller 800 is intended to include various forms of digital computers, such as printed circuit boards (PCB), processors, digital circuitry, or otherwise. Additionally, the system can include portable storage media, such as, Universal Serial Bus (USB) flash drives. For example, the USB flash drives may store operating systems and other applications. The USB flash drives can include input/output components, such as a wireless transmitter or USB connector that may be inserted into a USB port of another computing device.

The controller 800 includes a processor 810, a memory 820, a storage device 830, and an input/output device 840. Each of the components 810, 820, 830, and 840 are interconnected using a system bus 850. The processor 810 is capable of processing instructions for execution within the controller 800. The processor may be designed using any of a number of architectures. For example, the processor 810 may be a CISC (Complex Instruction Set Computers) processor, a RISC (Reduced Instruction Set Computer) processor, or a MISC (Minimal Instruction Set Computer) processor.

In one implementation, the processor 810 is a single-threaded processor. In another implementation, the processor 810 is a multi-threaded processor. The processor 810 is capable of processing instructions stored in the memory 820 or on the storage device 830 to display graphical information for a user interface on the input/output device 840.

The memory 820 stores information within the control system 800. In one implementation, the memory 820 is a computer-readable medium. In one implementation, the memory 820 is a volatile memory unit. In another implementation, the memory 820 is a non-volatile memory unit.

The storage device 830 is capable of providing mass storage for the controller 800. In one implementation, the storage device 830 is a computer-readable medium. In various different implementations, the storage device 830 may be a floppy disk device, a hard disk device, an optical disk device, a tape device, flash memory, a solid state device (SSD), or a combination thereof.

The input/output device 840 provides input/output operations for the controller 800. In one implementation, the input/output device 840 includes a keyboard and/or pointing device. In another implementation, the input/output device 840 includes a display unit for displaying graphical user interfaces.

The features described can be implemented in digital electronic circuitry, or in computer hardware, firmware, software, or in combinations of them. The apparatus can be implemented in a computer program product tangibly embodied in an information carrier, for example, in a machine-readable storage device for execution by a programmable processor; and method steps can be performed by a programmable processor executing a program of instructions to perform functions of the described implementations by operating on input data and generating output. The described features can be implemented advantageously in one or more computer programs that are executable on a programmable system including at least one programmable processor coupled to receive data and instructions from, and to transmit data and instructions to, a data storage system, at least one input device, and at least one output device. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors, and the sole processor or one of multiple processors of any kind of computer. Generally, a processor will receive instructions and data from a read-only memory or a random access memory or both. The essential elements of a computer are a processor for executing instructions and one or more memories for storing instructions and data. Generally, a computer will also include, or be operatively coupled to communicate with, one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, solid state drives (SSDs), and flash memory devices; magnetic disks such as internal hard disks and removable disks; magneto-optical disks; and CD-ROM and DVD-ROM disks. The processor and the memory can be supplemented by, or incorporated in, ASICs (application-specific integrated circuits).

To provide for interaction with a user, the features can be implemented on a computer having a display device such as a CRT (cathode ray tube) or LCD (liquid crystal display) or LED (light-emitting diode) monitor for displaying information to the user and a keyboard and a pointing device such as a mouse or a trackball by which the user can provide input to the computer. Additionally, such activities can be implemented via touchscreen flat-panel displays and other appropriate mechanisms.

The features can be implemented in a control system that includes a back-end component, such as a data server, or that includes a middleware component, such as an application server or an Internet server, or that includes a front-end component, such as a client computer having a graphical user interface or an Internet browser, or any combination of them. The components of the system can be connected by any form or medium of digital data communication such as a communication network. Examples of communication networks include a local area network (“LAN”), a wide area network (“WAN”), peer-to-peer networks (having ad-hoc or static members), grid computing infrastructures, and the Internet.

While this specification contains many specific implementation details, these should not be construed as limitations on the scope of any inventions or of what may be claimed, but rather as descriptions of features specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

A number of implementations have been described. Nevertheless, it will be understood that various modifications may be made without departing from the spirit and scope of the disclosure. For example, example operations, methods, or processes described herein may include more steps or fewer steps than those described. Further, the steps in such example operations, methods, or processes may be performed in different successions than that described or illustrated in the figures. Accordingly, other implementations are within the scope of the following claims.

What is claimed is:

1. A computer-implemented method of modeling a reservoir, comprising:
identifying, with a control system, a model of a wellbore that includes at least two tubing strings that are open in the wellbore and one or more fluid connections between the wellbore and a reservoir;
assigning, with the control system, each of the at least two tubing strings as a single string pseudo-well in the model of the wellbore;
numerically coupling, with the control system, the single string pseudo-wells together in the wellbore model;
determining, with the control system, one or more well parameters for the modeled wellbore; and
executing, with the control system, the modeled wellbore in a reservoir simulator to determine one or more wellbore fluid flow characteristics.

2. The computer-implemented method of claim 1, wherein each of the at least two tubing strings is assigned as an independent single string pseudo-well having an open end within the wellbore that is fluidly connected to the reservoir through at least one of the one or more fluid connections.

3. The computer-implemented method of claim 2, further comprising assigning, with the control system, one or more non-neighbor connections between grid cells of a discretized model of the reservoir and grid cells of a discretized model of a portion of the wellbore that includes the open end of each single string pseudo-well.

4. The computer-implemented method of claim 3, wherein each of the one or more non-neighbor connections comprises a virtual connection between two non-adjacent grid cells in the discretized model of the reservoir.

5. The computer-implemented method of claim 1, wherein determining one or more well parameters for the modeled wellbore comprises:
determining, with the control system, an effective permeability for each grid cell in a discretized model of at least a portion of the wellbore; and
determining, with the control system, a well connection transmissibility factor between each single string pseudo-well and the discretized model of the portion of the wellbore.

6. The computer-implemented method of claim 1, wherein a first tubing string comprises an injector and a second tubing string comprises a producer, and executing the modeled wellbore in a reservoir simulator to determine one or more wellbore fluid flow characteristics comprises:
executing, with the control system, the modeled wellbore in the reservoir simulator to determine a composition and flow rate of a first fluid produced from the producer based on a second fluid injected into the reservoir from the injector and a reservoir fluid.

7. The computer-implemented method of claim 6, wherein executing the modeled wellbore in the reservoir simulator to determine the composition and flow rate of the first fluid produced from the producer based on the second fluid injected into the reservoir from the injector and the reservoir fluid comprises:
determining, with the control system, the composition and flow rate of the first fluid based on a volume weighted average composition of the second fluid and the reservoir fluid.

8. A computing system, comprising:
one or more memory modules configured to store a model of a wellbore that includes at least two tubing strings that are open in the wellbore and one or more fluid connections between the wellbore and a reservoir; and
one or more hardware processors communicably coupled to the one or more memory modules and configured to execute instructions stored on the one or more memory modules to perform operations comprising:
assigning each of the at least two tubing strings as a single string pseudo-well in the model of the wellbore;
numerically coupling the single string pseudo-wells together in the wellbore model;
determining one or more well parameters for the modeled wellbore; and
executing the modeled wellbore in a reservoir simulator to determine one or more wellbore fluid flow characteristics.

9. The computing system of claim 8, wherein each of the at least two tubing strings is assigned as an independent single string pseudo-well having an open end within the wellbore that is fluidly connected to the reservoir through at least one of the one or more fluid connections.

10. The computing system of claim 9, wherein the operations further comprise assigning one or more non-neighbor connections between grid cells of a discretized model of the reservoir and grid cells of a discretized model of a portion of the wellbore that includes the open end of each single string pseudo-well.

11. The computing system of claim 10, wherein each of the one or more non-neighbor connections comprises a virtual connection between two non-adjacent grid cells in the discretized model of the reservoir.

12. The computing system of claim 8, wherein the operation of determining one or more well parameters for the modeled wellbore comprises:
determining an effective permeability for each grid cell in a discretized model of at least a portion of the wellbore; and
determining a well connection transmissibility factor between each single string pseudo-well and the discretized model of the portion of the wellbore.

13. The computing system of claim 8, wherein a first tubing string comprises an injector and a second tubing string comprises a producer, and the operation of executing the modeled wellbore in a reservoir simulator to determine one or more wellbore fluid flow characteristics comprises:
executing the modeled wellbore in the reservoir simulator to determine a composition and flow rate of a first fluid produced from the producer based on a second fluid injected into the reservoir from the injector and a reservoir fluid.

14. The computing system of claim 13, wherein the operation of executing the modeled wellbore in the reservoir simulator to determine the composition and flow rate of the first fluid produced from the producer based on the second fluid injected into the reservoir from the injector and the reservoir fluid comprises:
determining the composition and flow rate of the first fluid based on a volume weighted average composition of the second fluid and the reservoir fluid.

15. An apparatus comprising a tangible, non-transitory computer readable memory comprising instructions for causing one or more processors to perform operations comprising:
identifying a model of a wellbore that includes at least two tubing strings that are open in the wellbore and one or more fluid connections between the wellbore and a reservoir;
assigning each of the at least two tubing strings as a single string pseudo-well in the model of the wellbore;
numerically coupling the single string pseudo-wells together in the wellbore model;
determining one or more well parameters for the modeled wellbore; and
executing the modeled wellbore in a reservoir simulator to determine one or more wellbore fluid flow characteristics.

16. The apparatus of claim 15, wherein each of the at least two tubing strings is assigned as an independent single string pseudo-well having an open end within the wellbore that is fluidly connected to the reservoir through at least one of the one or more fluid connections.

17. The apparatus of claim 16, wherein the operations further comprise assigning one or more non-neighbor connections between grid cells of a discretized model of the reservoir and grid cells of a discretized model of a portion of the wellbore that includes the open end of each single string pseudo-well.

18. The apparatus of claim 17, wherein each of the one or more non-neighbor connections comprises a virtual connection between two non-adjacent grid cells in the discretized model of the reservoir.

19. The apparatus of claim 15, wherein the operation of determining one or more well parameters for the modeled wellbore comprises:
determining an effective permeability for each grid cell in a discretized model of at least a portion of the wellbore; and
determining a well connection transmissibility factor between each single string pseudo-well and the discretized model of the portion of the wellbore.

20. The apparatus of claim 15, wherein a first tubing string comprises an injector and a second tubing string comprises a producer, and the operation of executing the modeled wellbore in a reservoir simulator to determine one or more wellbore fluid flow characteristics comprises:
executing the modeled wellbore in the reservoir simulator to determine a composition and flow rate of a first fluid produced from the producer based on a second fluid injected into the reservoir from the injector and a reservoir fluid.

21. The apparatus of claim 20, wherein the operation of executing the modeled wellbore in the reservoir simulator to determine the composition and flow rate of the first fluid produced from the producer based on the second fluid injected into the reservoir from the injector and the reservoir fluid comprises:
determining the composition and flow rate of the first fluid based on a volume weighted average composition of the second fluid and the reservoir fluid.
